(19) United States
(12) Patent Application Publication
(10) Pub. No.: US 2004/0178485 A1
(43) Pub. Date: Sep. 16, 2004

(54) Semiconductor device housing plural stacked semiconductor elements

(75) Inventors: Tomokazu Otani, Tokyo (JP); Jun Nakai, Tokyo (JP)

Correspondence Address: McDERMOTT, WILL & EMERY, 600 13th Street, N.W., Washington, DC, 20005-3096, US

(73) Assignee: RENESAS TECHNOLOGY CORP.

(21) Appl. No.: 10/687,095

(22) Filed: Oct. 17, 2003

(30) Foreign Application Priority Data
Mar. 10, 2003 (JP) 2003-63050

(51) Int. Cl. H01L 23/02

(52) U.S. Cl. 257/678

(57) ABSTRACT

A semiconductor device includes a plurality of semiconductor elements each having a plurality of arranged pads, and the semiconductor elements are stacked and housed in the semiconductor device. The semiconductor device further includes a power supply frame that is bar-shaped and supplies a power voltage to at least two of the plurality of semiconductor elements.

### BACKGROUND OF THE INVENTION

1. Field of the Invention

The present invention relates to a semiconductor device and more particularly, to a structure of the semiconductor device housing a plurality of stacked semiconductor elements.

2. Related Art

There is a semiconductor device in which a plurality of semiconductor IC chips are stacked and housed in a package. In general, a plurality of power supply connection points (pads) are provided on each semiconductor IC chip housed in the semiconductor device. Conventionally, a power is supplied to each semiconductor IC chip through only one power supply pad. The reason for this is because an external lead for supplying a power to the semiconductor device is defined at one position, and thus when the plurality of power supply pads are connected to the power supply external lead by wire, problems arise in which the number of wires between the lead frame and the pads is increased and the wires intersect with each other.

In addition, Reference 1 (Japanese Patent Laid-Open Publication No. 5-129500) discloses a semiconductor device in which pads of the semiconductor chip are connected to a bar-shaped inner lead for supplying a power voltage by a bonding wire.

According to the above constitution in which power supply to the semiconductor IC chip is performed through the only one power supply pad, a stable power supply which is demanded for a semiconductor device offering a large capacity and a high-speed operation cannot be performed. More specifically, according to such a semiconductor device, when a plurality of semiconductor IC chips operate at the same time in the semiconductor device, power supply is brought to under harsh environments and the stable power supply to each semiconductor IC chip cannot be performed. As a result, there arises a problem of causing an operation defect of the semiconductor device.

It should be noted that the Reference 1 does not presuppose a semiconductor device in which a plurality of semiconductor chips are housed and not solve the above problem of the semiconductor device which arises when the plurality of semiconductor IC chips operate at the same time in the semiconductor device.

### SUMMARY OF THE INVENTION

The present invention was made to solve the above problems and it is an object of the present invention to provide a semiconductor device enabling a stable power supply to each semiconductor chip in the semiconductor device in which the plurality of semiconductor chips are stacked and housed.

A semiconductor device according to the present invention includes a plurality of semiconductor elements each having a plurality of arranged pads, and being stacked and housed in the semiconductor device, and a power supply frame that is bar-shaped and supplies a power voltage to at least two of the plurality of semiconductor elements.

### BRIEF DESCRIPTION OF THE DRAWINGS

FIG. 1A a view illustrating a structure of a semiconductor device according to a first embodiment of the present invention.

FIG. 1B is a top view showing a plurality semiconductor IC chips stacked and mounted in the semiconductor device according to the first embodiment.

FIG. 2A is a view illustrating a structure of a semiconductor device according to a second embodiment of the present invention.

FIG. 2B is a top view showing a plurality semiconductor IC chips stacked and mounted in the semiconductor device according to the second embodiment.

FIG. 3A illustrates a structure of a semiconductor device according to a third embodiment of the present invention.

FIG. 3B is a view showing a plurality semiconductor IC chips stacked and mounted in the semiconductor device according to the third embodiment, which is seen from a direction of an arrow A in FIG. 3A.

### DESCRIPTION OF THE PREFERRED EMBODIMENTS

Hereinafter, preferred embodiments of a semiconductor device according to the present invention are described in detail with reference to the accompanying drawings.

### First Embodiment

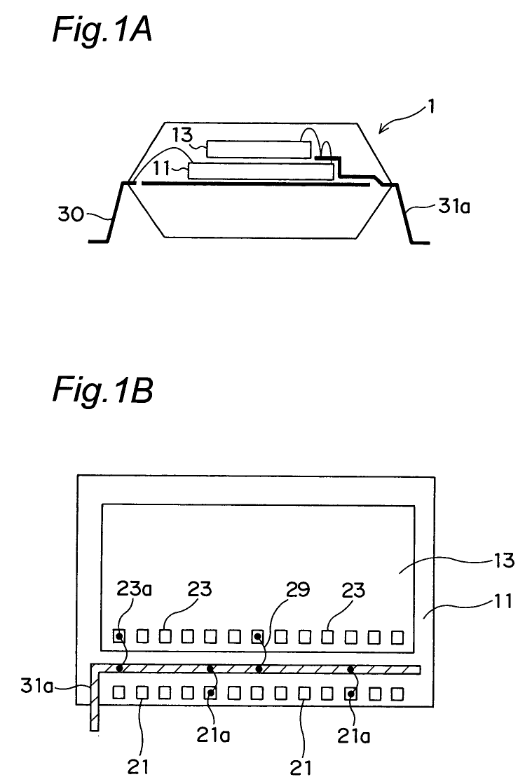

FIGS. 1A and 1B illustrate a structure of a semiconductor device according to the present invention. As shown in FIG. 1A, a semiconductor device 1 is a multichip package (MCP) housing a plurality of semiconductor IC chips 11 and 13 which are stacked and mounted on the semiconductor device 1. The semiconductor IC chip 11 is larger than the semiconductor IC chip 13 which is mounted on the semiconductor IC chip 11.

As shown in FIG. 1B, a plurality of pads (connection points) 21 and 23 are arranged on the semiconductor IC chips 11 and 13, respectively in the longitudinal direction thereof. The pads 21 and 23 are electrodes for supplying a power-supply voltage and transmitting signals to the semiconductor IC chips 11 and 13. The pads 21 and 23 include pads 21a and 23a for supplying the power-supply voltage, respectively. Each of the semiconductor IC chips 11 and 13 has the plurality of pads for supplying a power-supply voltage. Pads for the signal of the semiconductor IC chips 11 and 13 are connected to a lead frame 30 constituting an external terminal through a bonding wire, whereby signals are exchanged with an outside of the semiconductor device.

According to the semiconductor device 1 of the present embodiment, there is provided a power supply frame 31a formed of a bar-shaped conductor (metal, for example) as means for supplying a power-supply voltage to each of the semiconductor IC chips 11 and 13. The power supply frame 31a is formed by extending a lead frame for external connection and provided along a side surface of the semiconductor IC chip. The power supply frame 31a is provided on the larger semiconductor IC chip 11 between a row of the pads of the semiconductor IC chip 11 and a row of the pads of the semiconductor IC chip 13. Thus, both semiconductor IC chips 11 and 13 can share the power supply frame 31a.

As shown in FIG. 1B, the power supply pads 21a of the semiconductor IC chip 11 and the power supply pads 23a of the semiconductor IC chip 13 are connected to the power supply frame 31a through bonding wires 29. At this time, the plurality of power supply pads on each semiconductor IC chip are connected to the power supply frame 31a, thus resulting in improvement of a power supply ability to the semiconductor chip.

In addition, the power supply frame 31a is placed along and near the rows of the pads 21 and 23 of the semiconductor IC chips 11 and 13, and therefore there is an effect that a length of the bonding wire 29 for connecting the power supply frame 31a to the power supply pads 21a and 23a can be made shortest.

According to the semiconductor device of the present embodiment as described above, since the power supply frame for supplying a power-supply voltage is provided in the vicinity of the semiconductor IC chips, a power can be supplied to the plurality of power supply pads on the each of the semiconductor IC chips. This allows a power to be supplied stably in the semiconductor device in which the plurality of semiconductor IC chips operate at the same time.

Although the description was made of the example in which the semiconductor device houses two semiconductor IC chips in the above embodiment, the semiconductor device may store further more semiconductor IC chips.

### Second Embodiment

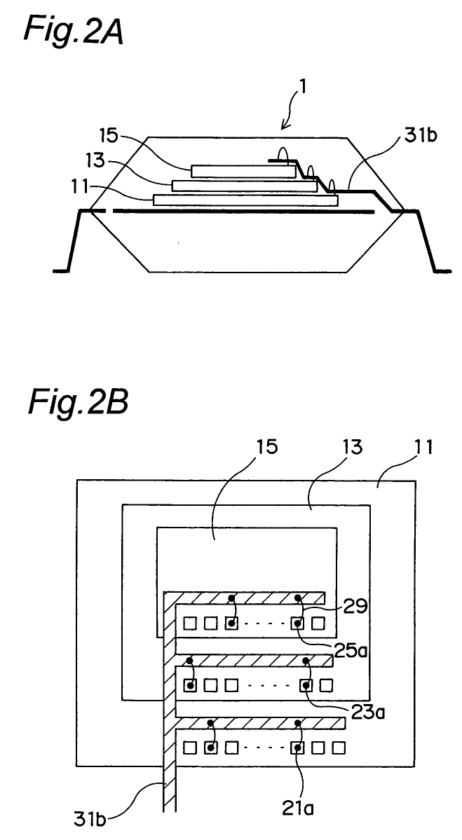

FIGS. 2A and 2B illustrate another structure of semiconductor device according to the present invention. According to the present embodiment, power supply to each of semiconductor chips is enabled by a common power supply frame 31b.

More specifically, the power supply frame 31b includes a portion extending in the longitudinal direction of each of the semiconductor IC chips in order to supply a power to respective power supply pads of stacked semiconductor IC chips 11, 13 and 15, and a portion coupling the parts extending in the longitudinal direction. The power supply frame 31b is provided so as to be bended in three dimensions along the side surface of the semiconductor IC chips in a semiconductor device 1.

It is necessary to provide wire bonding between the frames when the power supply frames are individually provided for each of the semiconductor IC chips. However, when the power supply frame is integrally formed for each of the semiconductor IC chips as shown in FIGS. 2A and 2B, the wire bonding between the frames is not necessary. According to the power supply frame of the present embodiment, like in the embodiment 1, a power can be supplied to the plurality of power voltage supply pads of each of the semiconductor IC chips and stable power supply can be implemented.

### Third Embodiment

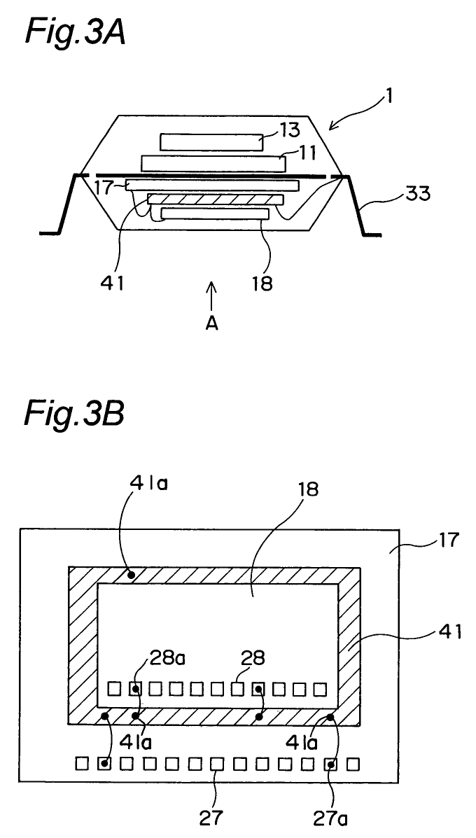

FIGS. 3A and 3B illustrate a still another structure of semiconductor device according to the present invention. According to the present embodiment, a spacer which is a member to be inserted at an assembly process in order to adjust heights between semiconductor devices in a package having a multilayer structure is used as power supply means.

As shown in FIG. 3A, a semiconductor IC chip 18 is stacked on a semiconductor IC chip 17 through a spacer 41. The spacer 41 is made of an electrically conductive material and functions as an electrically conductive member as well as a height adjusting member.

FIG. 3B is a figure of the semiconductor device viewed from a direction of an arrow A shown in FIG. 3A. Power supply points are provided in the spacer 41, and the power supply points 41a of the spacer 41 are connected to power supply pads 27a and 28a of semiconductor IC chips 17 and 18 by wire bonding. According to the present embodiment also, since a plurality of power supply pads 41a of one semiconductor IC chip are electrically connected to the spacer 41, power supply reinforcement can be implemented like in the above embodiments.

Since the spacer having electrical conductivity is used, it is not necessary to secure another area for placing the frame, and in addition, a stable power supply can be implemented while a predetermined height of the device is secured.

Furthermore, the whole of the spacer 41 is not necessarily formed of an electrically conductive material and only a part including the power supply points may be formed by the electrically conductive material.

According to the present invention, since a power-supply voltage is supplied to the plurality of pads of the semiconductor IC chip in the semiconductor device in which the plurality of stacked semiconductor chips are packaged, sufficient power supply can be implemented even when the plurality of semiconductor IC chips operate at the same time.

Although the present invention has been described in connection with specified embodiments thereof, many other modifications, corrections and applications are apparent to those skilled in the art. Therefore, the present invention is not limited by the disclosure provided herein but limited only to the scope of the appended claims.

The present disclosure relates to subject matter contained in Japanese Patent Application No. 2003-63050, filed on Mar. 10, 2003, which is expressly incorporated herein by reference in its entirety.

What is claimed is:

1. A semiconductor device comprising:
a plurality of semiconductor elements each having a plurality of arranged pads, the semiconductor elements being stacked and housed in the semiconductor device; and
a power supply frame that is bar-shaped and supplies a power voltage to at least two of the plurality of semiconductor elements.

2. The semiconductor device according to claim 1, wherein the power supply frame is provided on each of the semiconductor elements to which a power is supplied, and the power supply frame includes frame portions placed along rows of pads of the semiconductor elements and a portion coupling the frame portions.

3. The semiconductor device according to claim 1, wherein when the power supply frame supplies a power to two semiconductor elements, the power supply frame is provided on a larger semiconductor element of the two semiconductor elements.

4. The semiconductor device according to claim 3, wherein the power supply frame is placed between the rows of the pads of the two semiconductor elements.

5. A semiconductor device comprising:
a plurality of semiconductor elements each having a plurality of arranged pads, the semiconductor elements being stacked and housed in the semiconductor device; and
a spacer inserted between the semiconductor elements and having a electrical conductivity,
wherein the spacer is connected to the pads of at least the one semiconductor element by wire bonding.
